(19) United States
(12) Patent Application Publication
(10) Pub. No.: US 2025/0048588 A1
(43) Pub. Date: Feb. 6, 2025

(54) ELECTRONIC DEVICE

(71) Applicant: DENSO CORPORATION, Kariya-city (JP)

(72) Inventor: HIROKI CHITAKA, Kariya-city (JP)

(21) Appl. No.: 18/787,199

(22) Filed: Jul. 29, 2024

(30) Foreign Application Priority Data
Aug. 4, 2023 (JP) 2023-128127

(51) Int. Cl. H05K 7/20; H05K 1/02; H05K 1/14; H05K 5/00; H05K 5/06

(52) U.S. Cl. CPC H05K 7/20254; H05K 1/0203; H05K 1/14; H05K 5/0008; H05K 5/069; H05K 7/20272; H05K 7/2039

(57) ABSTRACT

An electronic device includes at least one circuit board and a housing. The housing includes a first housing member and a second housing member, at least one of which is provided with a housing part to house the circuit board therein. The first housing member and the second housing member are assembled together so that a hollow part that allows a liquid refrigerant to flow is provided between a facing surface of the first housing member and a facing surface of the second housing member. At least one of the first housing member or the second housing member is provided with an inlet/outlet port in communication with the hollow part. The housing part and the hollow part are separated from each other by the first housing member and the second housing member.

### CROSS REFERENCE TO RELATED APPLICATION

The present application claims the benefit of priority from Japanese Patent Application No. 2023-128127 filed on Aug. 4, 2023. The entire disclosures of the above application are incorporated herein by reference.

### TECHNICAL FIELD

The present disclosure relates to an electronic device.

### BACKGROUND

For example, an electronic device includes a circuit board, an electronic component disposed on the circuit board, and a heat conduction member disposed on the electronic component.

### SUMMARY

The present disclosure describes an electronic device. According to an aspect of the present disclosure, an electronic device includes a circuit board and a housing. The housing includes a first housing member and a second housing member, and at least one of the first housing member or the second housing member is provided with a housing part that houses the circuit board therein. The first housing member and the second housing member are assembled to each other so that surfaces thereof face each other as facing surfaces, and a hollow part that allows a liquid refrigerant to flow is defined between the facing surfaces the first housing member and the second housing member. The housing part and the hollow part are separated from each other by the first housing member and the second housing member.

### BRIEF DESCRIPTION OF DRAWINGS

FIG. 1 is a perspective view of an electronic device for showing a schematic configuration;

FIG. 2 is a cross-sectional view taken along a line II-II in FIG. 1;

FIG. 3 is a cross-sectional view taken along a line III-III in FIG. 1;

FIG. 4 is a perspective view of the electronic device for showing a schematic configuration on a first circuit board side;

FIG. 5 is a perspective view of the electronic device for showing a schematic configuration on a mounting surface side of a first housing member;

FIG. 6 is a perspective view of the electronic device for showing a schematic configuration on a facing surface side of the first housing member;

FIG. 7 is a perspective view of the electronic device for showing a schematic configuration on a second circuit board side;

FIG. 8 is a perspective view of the electronic device for showing a schematic configuration on a mounting surface side of a second housing member;

FIG. 9 is a perspective view of the electronic device for showing a schematic configuration on a facing surface side of the second housing member; and

FIG. 10 is an exploded perspective view of the electronic device for showing a schematic configuration of the electronic device.

### DETAILED DESCRIPTION

For example, an electronic device includes a circuit board, an electronic component disposed on the circuit board, and a heat conduction member disposed on the electronic component. In such an electronic device, it is conceivable to have a cooling section through which a liquid refrigerant flows in a space where the circuit board is housed. In such a configuration, there may be a fear that the circuit board will be wet with the liquid refrigerant leaking from the cooling section.

The present disclosure provides an electronic device capable of suppressing a circuit board from being wet.

According to an aspect of the present disclosure, an electronic device includes at least one circuit board and a housing. The housing includes a first housing member and a second housing member, and at least one of the first housing member or the second housing member is provided with a housing part that houses the at least one circuit board therein. The first housing member and the second housing member are assembled to each other so that surfaces thereof face each other as facing surfaces, and a hollow part that allows a liquid refrigerant to flow is defined between the facing surfaces the first housing member and the second housing member. At least one of the first housing member or the second housing member is provided with an inlet/outlet port that is in communication with the hollow part. The housing part and the hollow part are separated from each other by the first housing member and the second housing member.

In the electronic device having such a configuration, the housing part in which the circuit board is housed and the hollow part through which the liquid refrigerant flows are separated by the first housing member and the second housing member. Therefore, even if the liquid refrigerant leaks from the hollow part, it is less likely that the liquid refrigerant leaking from the hollow part will enter the housing part. In other words, the electronic device can suppress the circuit board from being wet.

Aspects disclosed in this specification adopt different technical solutions from each other in order to achieve their respective objectives. Objects, features, and advantageous effects disclosed in this specification will be more apparent by referring to the following detailed descriptions and the accompanying drawings.

Embodiments of the present disclosure will be described hereinafter with reference to the drawings. Hereinafter, three directions orthogonal to each other are referred to as an X direction, a Y direction, and a Z direction, respectively.

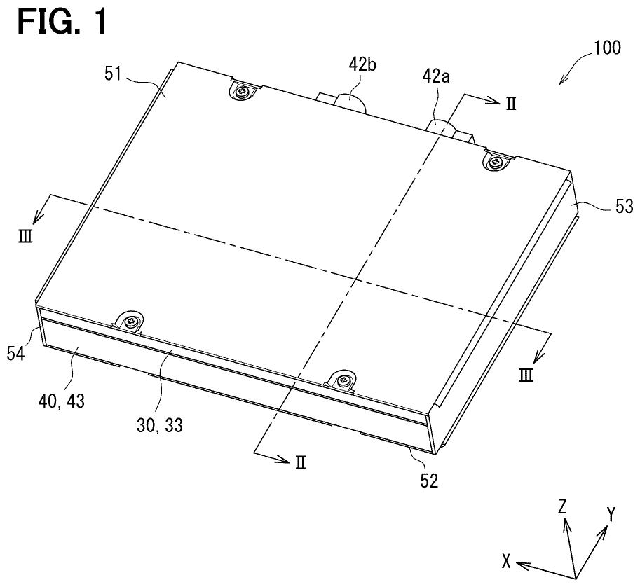

An electronic device 100 according to an embodiment will be described with reference to FIGS. 1 to 10. The electronic device 100 mainly includes a first circuit board 10, a second circuit board 20, a first housing member 30, and a second housing member 40. In the present embodiment, as an example, the electronic device 100 includes a first cover 51, a second cover 52, a third cover 53, and a fourth cover 54. The electronic device 100 is configured to cool the first circuit board 10 and the second circuit board 20 with cooling water CW1. The cooling water CW1 corresponds to a liquid refrigerant.

The electronic device 100 is configured so as to be mountable on a movable object such as a vehicle. For example, the electronic device 100 can be applied to an electronic control unit. The electronic device 100 can be applied to an integrated control unit in which multiple functions are integrated. The electronic device 100 can be applied to an electronic control unit for automatic driving. The respective components will be described below.

### <First Circuit Board>

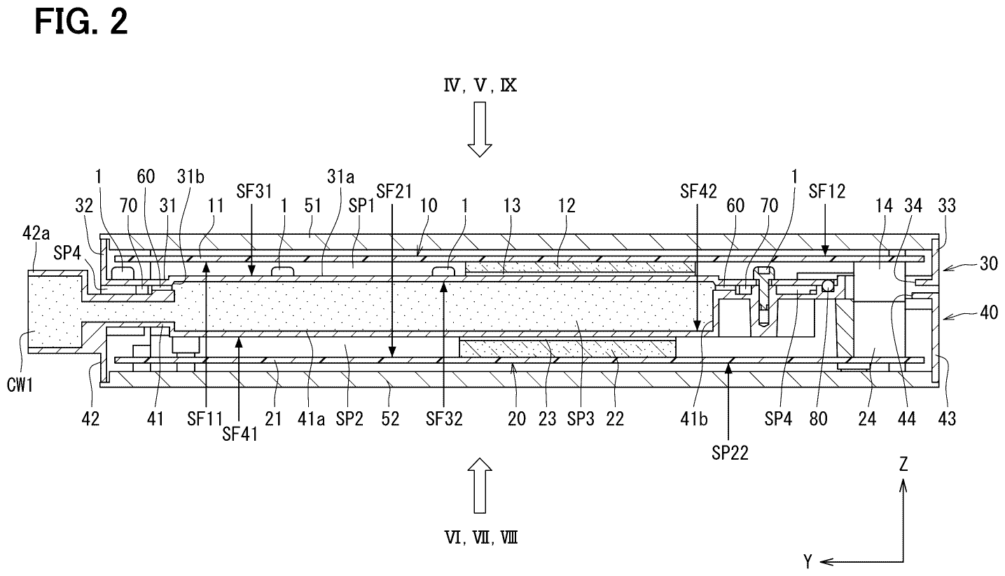

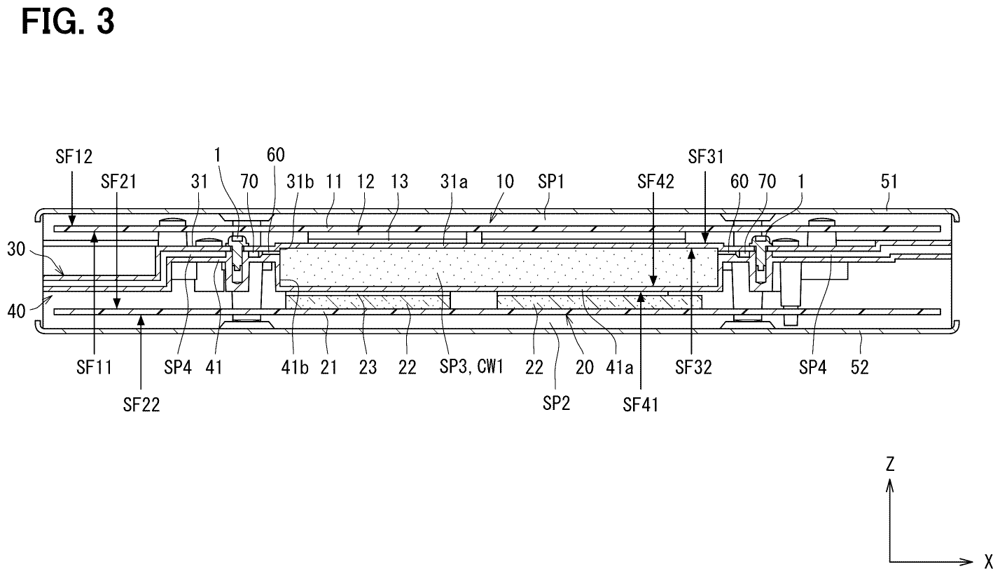

As shown in FIGS. 2 and 3, the first circuit board 10 includes a wiring board 11, a mounting component 12, a heat conduction member 13, a first connector 14, and the like. For example, the wiring board 11 has an electrically insulating base, which is made of a resin or the like, and a conductive wiring, which is made of copper or the like. The wiring board 11 is a so-called printed wiring board. The wiring board 11 has a mounting surface SF11 on which the mounting component 12 is mounted, and a back surface SF12 opposite the mounting surface SF11. The wiring board 11 is disposed along an XY plane.

The mounting component 12 is mounted on the mounting surface SF11. The mounting component 12 is electrically connected to the wiring of the wiring board 11. The mounting component 12 may be a SoC or the like. Therefore, the first circuit board 10 is configured so that the mounting component 12 executes an arithmetic processing. The first circuit board 10 can also be regarded as a single electronic control unit. “SoC” is an abbreviation for System on a Chip.

Circuit components other than the mounting component 12 may be mounted on the wiring board 11. The number of mounting component(s) 12 mounted on the wiring board 11 is not particularly limited. The wiring board 11 may have a circuit component on the back surface SF12.

The mounting component 12 is a circuit component that generates heat when in operation. The mounting component 12 corresponds to a heat generation component. The present embodiment thus employs an example in which the heat conduction member 13 is provided on the mounting component 12. The mounting component 12 is disposed to face a mounting surface SF31 of the first housing member 30, which will be described later. The mounting component 12 is mounted on the first housing member 30 via the heat conduction member 13. The heat conduction member 13 is in contact with the first housing member 30.

The heat conduction member 13 is a member for lowering a thermal resistance between the mounting component 12 and the first housing member 30. The heat conduction member 13 may be a heat dissipation gel or a heat dissipation sheet. The heat conduction member 13 is also referred to as a thermal interface material. The mounting surface SF31 corresponds to an opposite surface.

The first connector 14 is mounted on the mounting surface SF11. The first connector 14 is electrically connected to the wiring of the wiring board 11. The first connector 14 is an interface for electrically connecting the first circuit board 10 and the second circuit board 20.

### <Second Circuit Board>

As shown in FIG. 2 and FIG. 3, the second circuit board 20 includes a wiring board 21, a mounting component 22, a heat conduction member 23, a second connector 24, and the like. The second circuit board 20 has a similar structure to the first circuit board 10. In other words, components with the same names but different reference numerals are similar components to the components of the first circuit board 10.

The mounting component 22 is disposed to face a mounting surface SF41 of a second housing member 40, which will be described later. The mounting component 22 is mounted on the second housing member 40 via the heat conduction member 23. The mounting surface SF41 corresponds to an opposite surface.

The second circuit board 20 is electrically connected to the first circuit board 10 due to the second connector 24 and the first connector 14 being connected to each other. The first connector 14 and the second connector 24 can also be regarded as connectors for connecting the boards.

The second circuit board 20 differs from the first circuit board 10 in the number of mounting component(s) 22 and the contents of the arithmetic processing of the mounting component(s) 22. The wiring board 21 has a mounting surface SF21 on which the mounting component 22 is mounted, and a back surface SF22 opposite to the mounting surface SF21. The mounting component 22 corresponds to a heat generation component.

In the present embodiment, the electronic device 100 including the first circuit board 10 and the second circuit board 20 is employed. Alternatively, the electronic device 100 may also be configured to have either the first circuit board 10 or the second circuit board 20. As another example, the electronic device 100 may be configured such that the heat generation component is provided on either the first circuit board 10 or the second circuit board 20. Hereinafter, when there is no need to distinguish between the first circuit board 10 and the second circuit board 20, the first circuit board 10 and the second circuit board 20 will be collectively referred to as the circuit boards 10 and 20.

### <Housing>

As shown in FIG. 1, FIG. 2 and FIG. 3, a housing includes a first housing member 30 and a second housing member 40. The housing also includes a first cover 51, a second cover 52, a third cover 53, and a fourth cover 54. The housing is formed by assembling the first housing member 30, the second housing member 40, the first cover 51, the second cover 52, the third cover 53, and the fourth cover 54.

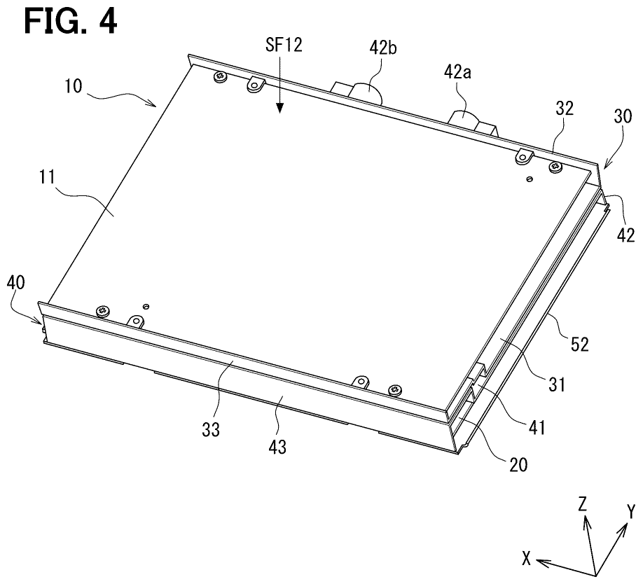

First, the first housing member 30 will be described with reference to FIG. 2 to FIG. 6. As shown in FIG. 2, FIG. 3 and FIG. 4, the first housing member 30 is a member that houses the first circuit board 10. The first housing member 30 can also be regarded as a member on which the first circuit board 10 is mounted. Therefore, the first housing member 30 can also be referred to as a mount member or a first mount member.

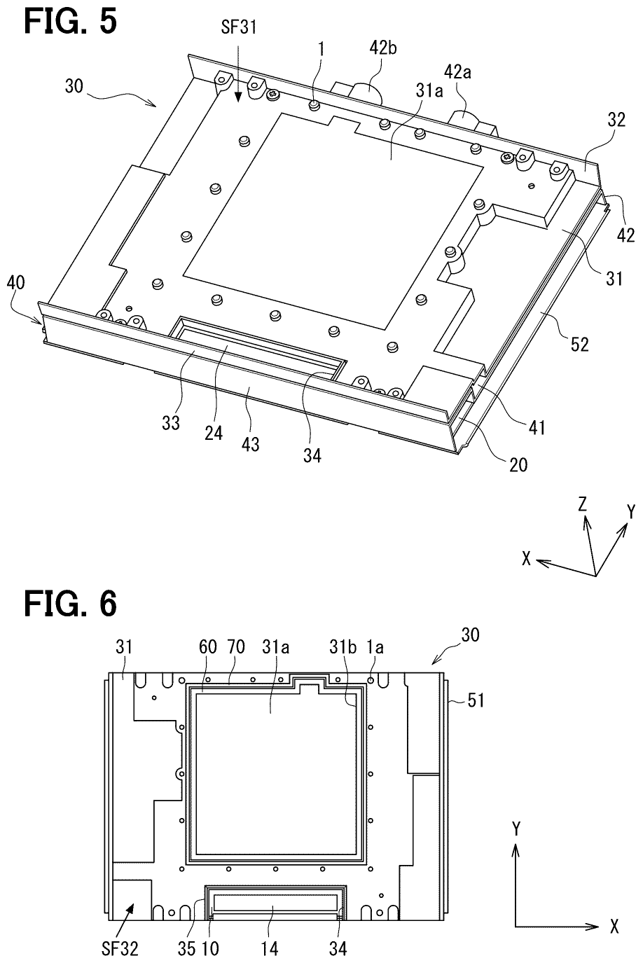

As shown in FIG. 5 and FIG. 6, the first housing member 30 includes a base portion 31 and side walls 32 and 33. The base portion 31 has a mounting surface SF31 on which the first circuit board 10 is mounted, and a facing surface SF32 opposite to the mounting surface SF31. The facing surface SF32 is a surface that faces the second housing member 40 when the first housing member 30 and the second housing member 40 are assembled together.

The side walls 32 and 33 are disposed at opposite ends of the base portion 31 in the Y direction. The side walls 32 and 33 protrude in the Z direction from the base portion 31. The side walls 32 and 33 extend along the X direction. The first housing member 30 has a first housing part SP1 for housing the first circuit board 10 in an area defined between the side wall 32 and the side wall 33. The first housing part SP1 corresponds to a facing area of the mounting surface SF31 and is an area defined between the side wall 32 and the side wall 33.

In a state where the first circuit board 10 is housed in the first housing member 30, the mounting surface SF11 of the first circuit board 10 faces the mounting surface SF31 of the first housing member 30. On the other hand, the back surface SF12 is exposed. Therefore, the first cover 51 is attached to the first housing member 30 in the facing area of the mounting surface SF31. In other words, the first cover 51 is attached to the first housing member 30 so as to cover the back surface SF12.

The third cover 53 and the fourth cover 54 are attached to the ends of the base portion 31 of the first housing member 30 along the Y direction. As another example, the first housing member 30 may be provided with side walls at the ends in the X direction so as to surround the first circuit board 10 together with the side walls 32 and 33. As further another example, the first housing member 30 may be provided with a side wall only on one of the ends in the X direction.

The base portion 31 includes a cooling section 31a. The cooling section 31a is a part that forms a hollow part SP3, which will be described later. The facing surface SF32 of the cooling section 31a is formed with a first recess 31b that is recessed more than its peripheral area. The facing surface SF32 of the cooling section 31a is a portion that comes into contact with the cooling water CW1. The first recess 31b corresponds to a recessed portion.

As shown in FIG. 2, FIG. 5, FIG. 6 and the like, the base portion 31 is formed with a first opening 34. The first opening 34 is a through hole that passes from the mounting surface SF31 to the facing surface SF32. The first opening 34 is disposed at a position closer to the side wall 33 than the side wall 32. The first connector 14 and the second connector 24, which are connected to each other, are partly disposed in the first opening 34.

As shown in FIG. 6, the base portion 31 is provided with a sealing portion 35 around the first opening 34. The sealing portion 35 is provided on the facing surface SF32. The sealing portion 35 is a portion in which a connector sealing member 80 is arranged, as will be described later. As an example, the sealing portion 35 has a groove shape to receive the connector sealing member 80 therein.

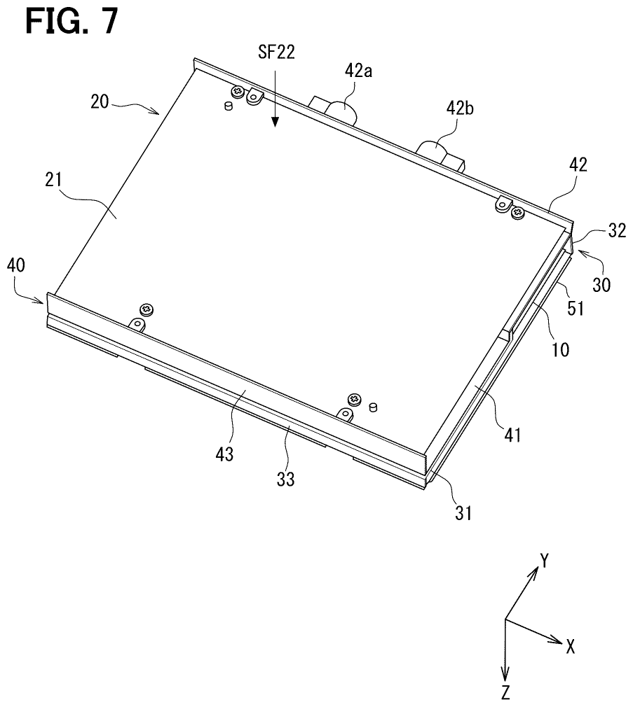

Next, the second housing member 40 will be described with reference to FIG. 2, FIG. 3, and FIG. 7 to FIG. 9. As shown in FIG. 2, FIG. 3 and FIG. 7, the second housing member 40 is a member that houses the second circuit board 20. The second housing member 40 can also be regarded as a member on which the second circuit board 20 is mounted. Therefore, the second housing member 40 can also be referred to as a mount member or a second mount member.

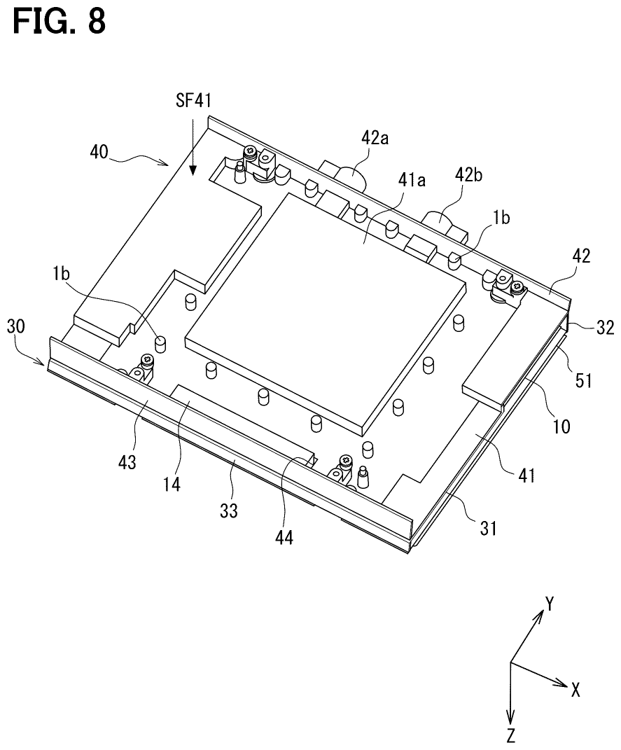

As shown in FIG. 7 and FIG. 8, the second housing member 40 includes a base portion 41 and side walls 42 and 43. The base portion 41 has a mounting surface SF41 on which the second circuit board 20 is mounted, and a facing surface SF42 opposite to the mounting surface SF41. The facing surface SF42 is a surface that faces the first housing member 30 when the first housing member 30 and the second housing member 40 are assembled together.

The side walls 42 and 43 are disposed at opposite ends of the base portion 41 in the Y direction. The side walls 42 and 43 protrude in the Z direction from the base portion 41. The side walls 42 and 43 extend along the X direction. The second housing member 40 has a second housing part SP2 for housing the second circuit board 20 in an area defined between the side wall 42 and the side wall 43. The second housing part SP2 corresponds to a facing area of the mounting surface SF41 and is an area defined between the side wall 42 and the side wall 43.

In a state where the second circuit board 20 is housed in the second housing member 40, the mounting surface SF21 of the second circuit board 20 faces the mounting surface SF41 of the second housing member 40. On the other hand, the back surface SF22 is exposed. Therefore, the second cover 52 is attached to the second housing member 40 in the facing area of the mounting surface SF41. In other words, the second cover 52 is attached to the second housing member 40 so as to cover the back surface SF22.

The third cover 53 and the fourth cover 54 are attached to the ends of the base portion 41 of the second housing member 40 along the Y direction. In this manner, the third cover 53 and the fourth cover 54 are provided to be shared between the first housing member 30 and the second housing member 40. Alternatively, in the present disclosure, the housing may not have the third cover 53 and the fourth cover 54. For example, electrical components such as external connection connectors may be attached in place of the third cover 53 and the fourth cover 54.

The second housing member 40 may be provided with side walls at the ends in the X direction to surround the second circuit board 20 together with the side wall 42 and the side wall 43. As another example, the second housing member 40 may be provided with a side wall only on one end in the X direction.

The base portion 41 includes a cooling section 41a. The cooling section 41a is a part that forms the hollow part SP3, which will be described later. In other words, the cooling section 41a is a part that forms the hollow part SP3 together with the cooling section 31a. The facing surface SF42 of the cooling section 41a is formed with a second recess 41b that is recessed from its peripheral area. The facing surface SF42 of the cooling section 41a is a portion that comes into contact with the cooling water CW1. The second recess 41b corresponds to a recessed portion.

In this manner, the hollow part SP3 is provided by the first recess 31b and the second recess 41b facing each other. Therefore, the electronic device 100 can have the hollow part SP3 that is larger than a hollow part in which either the first recess 31b or the second recess 41b is formed by a flat surface. For this reason, the electronic device 100 can increase the amount of the cooling water CW1. Accordingly, the electronic device 100 can efficiently cool the circuit board.

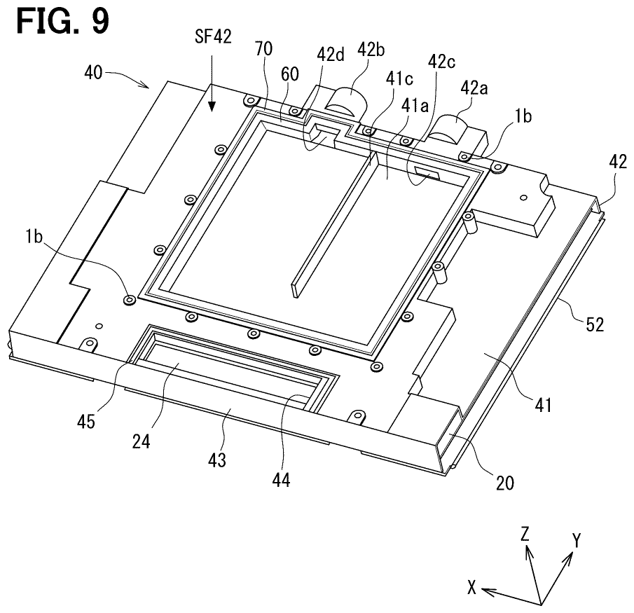

As shown in FIG. 2, FIG. 8, FIG. 9 and the like, the base portion 41 is formed with a second opening 44. The second opening 44 is a through hole that passes from the mounting surface SF41 to the facing surface SF42. The second opening 44 is disposed at a position closer to the side wall 43 than the side wall 42. The first connector 14 and the second connector 24, which are connected to each other, are partly disposed in the second opening 44.

As shown in FIG. 9, the base portion 41 has a sealing portion 45 provided around the second opening 44. The sealing portion 45 is disposed on the facing surface SF42. The sealing portion 45 is a portion in which the connector sealing member 80 is disposed, as will be described later. As an example, the sealing portion 45 has a groove shape to receive the connector sealing member 80 therein.

As shown in FIG. 9, an outlet portion 42a and an inlet portion 42b are provided to be continuous with the side wall 42. The outlet portion 42a and the inlet portion 42b are provided integrally with the side wall 42. Therefore, it can be said that the outlet portion 42a and the inlet portion 42b are provided adjacent to each other on the same side wall 42.

The outlet portion 42a is a portion to which an outlet pipe through which the cooling water CW1 flows is attached. The outlet portion 42a is formed with an outlet port 42c which is a through hole in communication with the hollow part SP3. The cooling water CW1 flowing through the hollow part SP3 passes through the outlet port 42c and flows out to the outlet pipe.

The inlet portion 42b is a portion to which an inlet pipe through which the cooling water CW1 flows is attached. The inlet portion 42b is formed with an inlet port 42d which is a through hole in communication with the hollow part SP3. The cooling water CW1 is supplied into the hollow part SP3 from the inlet pipe through the inlet port 42d.

The second housing member 40 has a wall portion 41c that protrudes into the hollow part SP3. The wall portion 41c is a portion of the cooling portion 41a that protrudes toward the facing surface SF42. The wall portion 41c has a height, for example, approximately equal to the depth of the second recess 41b. Alternatively, the wall portion 41c may have a height approximately equal to the depth of the hollow part SP3 in the Z direction. The height of the wall portion 41c is the dimension in the Z direction. The length or depth of the hollow part SP3 corresponds to the distance between the facing surface SF32 and the facing surface SF42 in the hollow part SP3.

The wall portion 41c is disposed between the outlet port 42c and the inlet port 42d. In other words, the wall portion 41c is connected to a wall defining the second recess 41b adjacent to the side wall 42, between the outlet port 42c and the inlet port 42d. The wall portion 41c is disposed along the Y direction without reaching a wall defining the second recess 41b adjacent to the side wall 43. In this manner, the wall portion 41c partially divides the hollow part SP3 into an outlet port 42c side and an inlet port 42d side. This wall portion 41c may be provided on at least one of the first housing member 30 or the second housing member 40. The wall portion 41c can also be referred to as a flow adjusting portion or a flow adjusting wall that adjusts or rectifies the flow of the liquid refrigerant.

The outlet port 42c and the inlet port 42d correspond to an inlet/outlet port. The outlet pipe and the inlet pipe correspond to pipes. The outlet pipe can also be regarded as a pipe attached to the outlet port 42c. The inlet pipe can also be regarded as a pipe attached to the inlet port 42d.

In the present embodiment, as an example, a configuration in which the outlet portion 42a and the inlet portion 42b are provided in the second housing member 40 is employed. Alternatively, the outlet portion 42a and the inlet portion 42b may be provided in the first housing member 30. As further another example, the outlet portion 42a may be provided in one of the first housing member 30 or the second housing member 40, and the inlet portion 42b may be provided in the other.

One of the outlet portion 42a and the inlet portion 42b may be provided on the side wall 42, and the other may be provided on the side wall 43. In other words, the electronic device 100 may be configured so that the coolant CW1 flows linearly.

Thus, the electronic device 100 has, as a housing part, a first housing part SP1 and a second housing part SP2. The first housing member 30 and the second housing member 40 are provided with the housing part SP1 and the housing part SP2. Therefore, the first housing member 30 and the second housing member 40 correspond to an accommodation housing member. However, the present disclosure can also be adopted in a configuration in which the housing parts SP1 and SP2 are provided in at least one of the first housing member 30 or the second housing member 40.

The first housing member 30 and the second housing member 40 are mainly made of a metal such as aluminum. However, the material of the first housing member 30 and the second housing member 40 is not limited to such an example. Only one of the first housing member 30 or the second housing member 40 may be made of a metal as a main component. For example, the first housing member 30 and/or the second housing member 40 may be made of a material mainly composed of a resin.

### <Electronic Device>

Here, assembling of the components as described above and the electronic device 100 in the assembled state will be described.

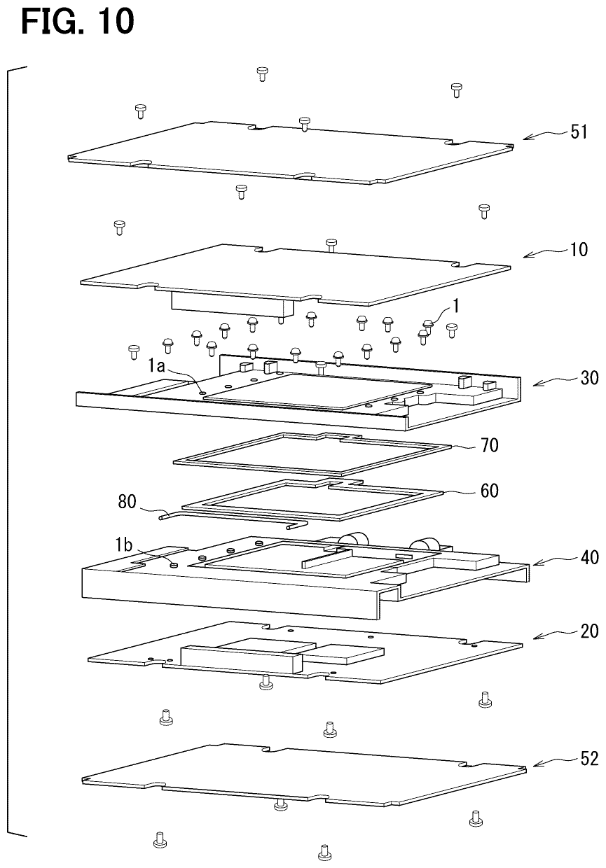

As shown in FIG. 10, the electronic device 100 includes the first circuit board 10, the second circuit board 20, the first housing member 30, the second housing member 40, the first cover 51, and the second cover 52 as separate components. Further, the electronic device 100 includes the sealing member 60, a gasket 70, and the connector sealing member 80 as separate components.

The electronic device 100 is formed by stacking and assembling these components. The electronic device 100 is assembled such that the facing surface SF32 of the first housing member 30 and the facing surface SF42 of the second housing member 40 face each other. The first housing member 30 and the second housing member 40 are fixed together by screw members 1, which are male screws. As shown in FIG. 6, the first housing member 30 is formed with screw openings 1a into which the screw members 1 are inserted. On the other hand, the second housing member 40 is formed with screw holes 1b into which the screw members 1 are fastened, as shown in FIG. 9. The screw holes 1b are formed with female threads. The first housing member 30 and the second housing member 40 are fixed together by fastening the screw members 1 to the screw holes 1b while passing through the screw openings 1a.

Further, when the first housing member 30 and the second housing member 40 are assembled together, the hollow part SP3 is formed by the facing surfaces SF32 and SF42. The hollow part SP3 provides a space through which the cooling water CW1 flows. Therefore, the hollow part SP3 can also be regarded as a refrigerant flow path.

As shown in FIG. 2, FIG. 3, FIG. 6 and FIG. 9, the sealing member 60 is provided between the first housing member 30 and the second housing member 40 so as to surround the entire perimeter of the hollow part SP3. It can also be said that the sealing member 60 is provided in the facing region between the first housing member 30 and the second housing member 40. That is, the first housing member 30 and the second housing member 40 are fixed together in the state where the sealing member 60 is disposed in the facing region.

The sealing member 60 restricts the cooling water CW1 from leaking from the hollow part SP3. The sealing member 60 may be provided by an O-ring, a caulking material, or the like.

The sealing member 60 is in contact with the first housing member 30 and the second housing member 40. More specifically, the sealing member 60 is in contact with the facing surfaces SF32 and SF42. Furthermore, the sealing member 60 is arranged in a pressed stated by the facing surfaces SF32 and SF42 due to the screw members 1 being fixed as described above. As such, the electronic device 100 restricts the leakage of the cooling water CW1 from the hollow part SP3.

As shown in FIG. 6 and FIG. 9, the screw members 1 are provided at multiple locations on the outer periphery of the sealing member 60. In other words, the screw members 1 are disposed at multiple locations so as to surround the sealing member 60. The screw members 1 are disposed at multiple locations on each side of the sealing member 60 along the Y direction. The screw members 1 are disposed at multiple locations on each side of the sealing member 60 along the X direction. The screw members 1 are disposed at two locations on opposite sides of the outlet port 42c and at two locations on opposite sides of the inlet port 42d.

In the electronic device 100, therefore, the first housing member 30 and the second housing member 40 can press the sealing member 60 along its entire periphery, improving the sealing performance. In other words, the electronic device 100 can improve the function of suppressing the leakage by the sealing member 60.

Note that the electronic device 100 may not have the sealing member 60. For example, the first housing member 30 and the second housing member 40 are welded together so as to surround the entire perimeter of the hollow part SP3. Also in this case, it is possible to restrict the leakage of the cooling water CW1 from the hollow part SP3.

As shown in FIG. 2, FIG. 3, FIG. 6 and FIG. 9, the gasket 70 is provided in the facing region between the first housing member 30 and the second housing member 40. The gasket 70 is disposed to surround entirely the periphery of the sealing member 60. It can also be said that the gasket 70 is disposed on the outer periphery of the sealing member 60. In other words, the first housing member 30 and the second housing member 40 are fixed together in the state where the gasket 70 is disposed in the facing region.

As described above, the electronic device 100 includes the sealing member 60 for restricting the leakage of the cooling water CW1 from the hollow part SP3. However, the cooling water CW1 may leak due to deterioration or the like of the sealing member 60. The gasket 70 is a member for restricting the leaking cooling water CW1 from scattering forcefully even if the cooling water CW1 leaks. The gasket 70 corresponds to a scatter restriction member.

The material of the gasket 70 is not particularly limited. It is preferable that the gasket 70 is in contact with both of the facing surfaces SF32 and SF42. Alternatively, it is sufficient that the gasket 70 is in contact with at least one of the facing surface SF32 or the facing surface SF42. Also, the gasket 70 may be employed in a portion protruding from at least one of the facing surface SF32 or the facing surface SF42.

As a result, even if the cooling water CW1 leaks from the hollow part SP3, the electronic device 100 can restricts the leaked liquid cooling water CW1 from flowing out forcefully. The screw members 1 may be disposed at multiple locations on the outer periphery of the gasket 70. Alternatively, the electronic device 100 may not have the gasket 70.

As described above, the second housing member 40 has the wall portion 41c. Therefore, in the state where the first housing member 30 and the second housing member 40 are assembled together, the wall portion 41c is disposed in the hollow part SP3. The wall portion 41c allows the cooling water CW1 to flow in a U-shape within the hollow part SP3. Therefore, the electronic device 100 can be configured so that the cooling water CW1 can easily flow throughout the entire hollow part SP3.

More specifically, in the present embodiment, as an example, the inlet port 42d and the outlet port 42c are provided adjacent to one side wall 42. Therefore, the cooling water CW1 flows into the hollow part SP3 from the inlet port 42d, flows throughout the entire hollow part SP3, and thus easily flows out from the outlet port 42c. As such, it is possible to restrict the cooling water CW1 from stagnating partly in the hollow part SP3. With this, the electronic device 100 can have a larger cooling space. However, the electronic device 100 may not have the wall portion 41c.

As shown in FIG. 2 and FIG. 3, a gap SP4 that communicates with the external space is provided on the outer periphery of the sealing member 60 between the facing surfaces SF32 and SF42. In other words, in the electronic device 100, the facing surface SF32 and the facing surface SF42 are not in contact with each other on the outer periphery of the sealing member 60 in the state where the first housing member 30 and the second housing member 40 are assembled together. The gap SP4 can be regarded as a facing region defined between the facing surface SF32 and the facing surface SF42 on the periphery of the sealing member 60.

Note that the external space is a space in which the electronic device 100 is placed. The external space can also be regarded as the space surrounding the electronic device 100. As such, the electronic device 100 allows the cooling water CW1 to be released to the external space even if the cooling water CW1 leaks from the hollow part SP3. Alternatively, the electronic device 100 may not have the gap SP4. As another example, the gap SP4 may be provided only in a part on the periphery of the sealing member 60.

The connector sealing member 80 is provided between the first housing member 30 and the second housing member 40 around the first opening 34 and the second opening 44. That is, the first housing member 30 and the second housing member 40 are fixed together in a state where the connector sealing member 80 is disposed in the sealing portions 35 and 45.

The connector sealing member 80 is in contact with the sealing portions 35 and 45. More specifically, the connector sealing member 80 is disposed in a pressed state by the sealing portions 35 and 45, as the screw members 1 being fixed. Therefore, the electronic device 100 can restrict the first connector 14 and the second connector 24 from being wet even if the cooling water CW1 leaks from the hollow part SP3.

In this manner, the base part of the housing having the hollow part SP3 and the gap SP4 is formed by fixing the first housing member 30 and the second housing member 40 with the screw members 1. As shown in FIG. 4, FIG. 7 and the like, the first circuit board 10 and the second circuit board 20 are mounted on the base part. In other words, the first circuit board 10 is mounted on the first housing member 30. The second circuit board 20 is mounted on the second housing member 40. The housing members 30 and 40 and the circuit boards 10 and 20 are fixed together by screws or the like.

As a result, as shown in FIG. 2 and FIG. 3, the first circuit board 10 and the second circuit board 20 are fixed so as to interpose the base portion 31 of the first housing member 30 and the base portion 41 of the second housing member 40 therebetween. Further, the cooling sections 31a and 41a are disposed between the first circuit board 10 and the second circuit board 20. The hollow part SP3 is thus provided between the first circuit board 10 and the second circuit board 20. Therefore, the electronic device 100 can cool the first circuit board 10 and the second circuit board 20 by the cooling water CW1 flowing through the single hollow part SP3. In other words, the hollow part SP3 can be regarded as a refrigerant space provided in common to the first circuit board 10 and the second circuit board 20.

It is preferable that the circuit boards 10 and 20 are respectively disposed so that the mounting components 12 and 22 face the cooling sections 31a and 41a. In such a case, the electronic device 100 can efficiently cool the mounting components 12 and 22.

In particular, the electronic device 100 includes the first circuit board 10 and the second circuit board 20. In the electronic device 100, it is conceivable that the number of mounting components 12 and 22 and the calculations performed by the respective mounting components 12 and 22 increase in accordance with the integration of functions. With this, the amount of heat generated by the electronic device 100 may increase. In contrast, the electronic device 100 can cool the first circuit board 10 and the second circuit board 20 with the cooling water CW1. Therefore, the electronic device 100 can operate the first circuit board 10 and the second circuit board 20 at appropriate temperatures. In other words, the electronic device 100 can withstand the increase in the number of mounting components 12 and 22 and the increase in the calculations performed by each of the mounting components 12 and 22. In addition, the electronic device 100 can maintain stable operation even if the number of mounting components 12 and 22 and the amount of calculation of each of the mounting components 12 and 22 increase.

In the present embodiment, as an example, the first housing member 30 and the second housing member 40 are mainly made of a metal. Therefore, the electronic device 100 can improve the cooling effect of the circuit boards 10 and 20 by the cooling water CW1.

However, the present disclosure is not limited to the example described above. Only one of the first housing member 30 or the second housing member 40 may be made of metal as a main component. In a configuration in which a circuit board is mounted on only one of the first housing member 30 or the second housing member 40, it is preferable that the one on which the circuit board is mounted is made of a metal as a main component. In other words, it is preferable that either the first housing member 30 or the second housing member 40 in which the housing part SP1 or SP2 is formed is made of a metal as a main component. In such a case, the electronic device 100 can improve the cooling effect of the circuit board by the cooling water CW1.

The first housing member 30 has the two side walls 32 and 33 that define the first housing part SP1 therebetween. Similarly, the second housing member 40 has the two side walls 42 and 43 that define the second housing part SP2 therebetween. With such configurations, the electronic device 100 can further suppress the cooling water CW1 from entering the housing parts SP1 and SP2 even if the cooling water CW1 leaks from the hollow part SP3.

Meanwhile, pipes through which the cooling water CW1 flows are attached to the outlet portion 42a and the inlet portion 42b. Therefore, there is a possibility that the cooling water CW1 may flow out from the attachment portions between the outlet portion 42a and the inlet portion 42b and the pipes.

However, as shown in FIG. 2, FIG. 7 and the like, the second housing member 40 has the side wall 42 between the second housing part SP2 and the outlet portion 42a and the inlet portion 42b. Similarly, as shown in FIG. 2, FIG. 4 and the like, the first housing member 30 has the side wall 32 between the first storage portion SP1 and the outlet portion 42a and the inlet portion 42b. In other words, the side wall 32 separates the outlet portion 42a and the inlet portion 42b from the first housing part SP1. The side wall 42 divides the outlet portion 42a and the inlet portion 42b from the second housing part SP2. Therefore, the electronic device 100 can restrict the cooling water CW1 leaking from the attachment portions between the outlet portion 42a and the inlet portion 42b and the pipes from reaching the circuit boards 10 and 20.

### Advantageous Effects

As described above, in the electronic device 100, the housing parts SP1 and SP2 in which the circuit boards 10 and 20 are housed are separated from the hollow part SP3 through which the cooling water CW1 flows by the first and second housing members 30 and 40, respectively. In other words, the housing parts SP1 and SP2 are separated from the hollow part SP3 by at least the base portions 31 and 41. Further, the housing parts SP1 and SP2 and the hollow section SP3 are separate spaces from each other.

Therefore, even if the cooling water CW1 leaks from the hollow part SP3, the electronic device 100 can restrict the cooling water CW1 from entering the housing parts SP1 and SP2. In other words, the electronic device 100 can restrict the circuit boards 10 and 20 from being wet.

Although the present disclosure has been described in accordance with the embodiments and examples, it is understood that the present disclosure is not limited to such embodiments or examples. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

What is claimed is:

1. An electronic device comprising:
at least one circuit board; and
a housing including a first housing member and a second housing member, at least one of the first housing member or the second housing member being provided with a housing part in which the at least one circuit board is housed, wherein
the first housing member and the second housing member are assembled together so that a hollow part that allows a liquid refrigerant to flow is provided between a facing surface of the first housing member and a facing surface of the second housing member,
at least one of the first housing member or the second housing member is provided with an inlet/outlet port in communication with the hollow part, and
the housing part and the hollow part are separated from each other by the first housing member and the second housing member.

2. The electronic device according to claim 1, further comprising:
a sealing member provided between the first housing member and the second housing member to surround the hollow part, wherein
the sealing member is in contact with the first housing member and the second housing member.

3. The electronic device according to claim 2, further comprising:
a scatter restriction member disposed in a facing region between the first housing member and the second housing member to surround the sealing member.

4. The electronic device according to claim 2, wherein
a gap is provided between the facing surface of the first housing member and the facing surface of the second housing member on a periphery of the sealing member, the gap being in communication with an external space.

5. The electronic device according to claim 2, wherein
the first housing member and the second housing member are assembled to each other and fixed to each other by a screw member.

6. The electronic device according to claim 5, wherein
the screw member is one of a plurality of screw members provided at a plurality of locations on a periphery of the sealing member.

7. The electronic device according to claim 1, wherein
the at least one of the first housing member or the second housing member, which is provided with the housing part, is an accommodation housing member, and
the accommodation housing member is made of a metal as a main component.

8. The electronic device according to claim 1, wherein
the at least one of the first housing member or the second housing member, which is provided with the housing part, is an accommodation housing member, and
the accommodation housing member has two side walls on opposite sides of the housing part.

9. The electronic device according to claim 1, wherein
at least one of the facing surface of the first housing member or the facing surface of the second housing member is formed with a recessed portion recessed from a peripheral portion, and
the hollow part is provided by the recessed portion.

10. The electronic device according to claim 1, wherein
the circuit board includes a first circuit board and a second circuit board,
the first housing member has a first housing part, as the housing part, to house the first circuit board therein,
the second housing member has a second housing part, as the housing part, to house the second circuit board therein, and
the hollow part is located between the first circuit board and the second circuit board.

11. The electronic device according to claim 10, wherein
at least one of the first circuit board or the second circuit board has a heat generation component thereon, and
the heat generation component is disposed on an opposite surface of the at least one of the first circuit board or the second circuit board, the opposite surface being opposite to the corresponding facing surface.

12. The electronic device according to claim 10, wherein
the first circuit board includes a first connector,
the second circuit board includes a second connector electrically connected to the first connector,
the first housing member is formed with a first opening in which the first connector and the second connector, which are connected to each other, are partly located,
the second housing member is formed with a second opening in which the first connector and the second connector, which are connected to each other, are partly located, and
a connector sealing member is provided on a periphery of the first opening and the second opening, between the first housing member and the second housing member.

13. The electronic device according to claim 1, further comprising:
a pipe connected to the inlet/outlet port to allow the liquid refrigerant to flow.

14. The electronic device according to claim 1, wherein
at least one of the first housing member and the second housing member has a wall portion protruding into the hollow part, and
the inlet/outlet port includes an inlet port and an outlet port, and the wall portion is located between the inlet port and the outlet port.
